(19) United States
(12) Patent Application Publication
(10) Pub. No.: US 2026/0090445 A1
(43) Pub. Date: Mar. 26, 2026

(54) SEMICONDUCTOR DEVICE

(71) Applicant: Samsung Electronics Co., Ltd., Suwon-si (KR)

(72) Inventors: Byungwook KIM, Suwon-si (KR); Hyojung KO, Suwon-si (KR); Kyungseob OH, Suwon-si (KR); Jaekul LEE, Suwon-si (KR); Sunwoo HAN, Suwon-si (KR)

(73) Assignee: Samsung Electronics Co., Ltd., Suwon-si (KR)

(21) Appl. No.: 19/087,671

(22) Filed: Mar. 24, 2025

(30) Foreign Application Priority Data
Sep. 26, 2024 (KR) 10-2024-0130672

(51) Int. Cl. H01L 23/00

(52) U.S. Cl. CPC H10W 72/90; H10W 70/652; H10W 72/20; H10W 72/244; H10W 72/29; H10W 72/932; H10W 72/934; H10W 72/942; H10W 72/9445

(57) ABSTRACT

Example embodiments are directed to a semiconductor device including a substrate, a substrate pad placed on the substrate, a substrate insulation layer configured to surround at least a portion of the substrate pad, a passivation layer placed on the substrate insulation layer and a bump pad placed on the passivation layer, electrically connected to the substrate pad and including solder bumps. The bump pad includes a connector recessed toward the substrate, and the connector, when viewed in a first direction perpendicular to a surface of the substrate, includes a shape, in order to reduce or lower a defect occurring in solder bumps when a degree of expansion and contraction varies due to differences in the coefficient of thermal expansion (CTE).

### CROSS-REFERENCE TO RELATED APPLICATIONS

This application claims priority under 35 U.S.C. § 119 to Korean Patent Application No. 10-2024-0130672, filed on Sep. 26, 2024, in the Korean Intellectual Property Office, the disclosure of which is incorporated herein by reference in its entirety.

### BACKGROUND

Example embodiments relate to a semiconductor device.

In order to electrically connect a printed circuit board (PCB) and a semiconductor device, the semiconductor device may include solder bumps. Defects such as cracks may occur in the solder bumps due to thermal expansion or physical shock. Due to the difference in coefficient of thermal expansion (CTE) between the printed circuit substrate containing resin components and the semiconductor device containing silicon, the degree of expansion and contraction in the solder bumps may vary, and defects may occur in the solder bumps.

### SUMMARY

Example embodiments provide a semiconductor device that reduces (or, alternatively, lowers) defects occurring in solder bumps when the degree of expansion and contraction varies depending on the difference in the CTE.

The technical effects to be achieved by the example embodiments are not limited to the technical effects described above, and other technical effects may be inferred from the following example embodiments by those skilled in the art.

According to some example embodiments, a semiconductor device includes a substrate, a substrate pad placed on the substrate, a substrate insulation layer configured to surround at least a portion of the substrate pad, a passivation layer placed on the substrate insulation layer, and a bump pad placed on the passivation layer, electrically connected to the substrate pad and including solder bumps. The bump pad includes a connector recessed toward the substrate. The connector, when viewed in a first direction perpendicular to a surface of the substrate, includes a shape including at least one of a first shape, a second shape, and a third shape. The first shape has a first length L₁ shorter than a second length L₂ and a third length L₃. The first length L₁ is along a first axis direction passing through a center of the bump pad and toward the center of the substrate. The second length L₂ is along a second axis direction that is rotated 45 degrees counterclockwise from the first axis direction while passing through the center of the bump pad. The third length L₃ is along a third axis direction that is rotated 45 degrees clockwise from the first axis direction while passing through the center of the bump pad. The second shape has the first length L₁ shorter than a major axis length L_{A} of the connector parallel to the second axis direction and a major axis length L_{B} of the connector parallel to the third axis direction. The second shape is different from the first shape. The third shape has a sum of a surface area of the connector in a first area rotated 45 degrees counterclockwise to 135 degrees counterclockwise from the first axis direction and a surface area of the connector in a third area rotated 45 degrees clockwise to 135 degrees clockwise from the first axis direction greater than a sum of a surface area of the connector in a second area rotated 135 degrees counterclockwise to 225 degrees counterclockwise from the first axis direction and a surface area of the connector in a fourth area rotated 45 degrees clockwise or 45 degrees counterclockwise from the first axis direction. The third shape is different from the first shape and the second shape.

According to some example embodiments, a semiconductor device includes a substrate including a first area extending from an edge toward a center of the substrate and a second area that is an area of the substrate excluding the first area; a first substrate pad on the first area and a second substrate pad on the second area; a substrate insulation layer surrounding at least a portion of each of the first substrate pad and the second substrate pad; a passivation layer on the substrate insulation layer; a first bump pad on the passivation layer, electrically connected to the first substrate pad, and including a first solder bump; and a second bump pad on the passivation layer, electrically connected to the second substrate pad, and including a second solder bump. The first bump pad includes a first connector that is recessed toward the first area, and the second bump pad comprises a second connector that is recessed toward the second area. The first connector, when viewed in a first direction perpendicular to a surface of the substrate, includes a shape including at least one of a first shape, a second shape, and a third shape. The first shape has a first length L₁ shorter than a second length L₂ and a third length L₃. The first length L₁ is along a first axis direction passing through a center of the first bump pad toward a center of the substrate. The second length L₂ is along a second axis direction that is rotated 45 degrees counterclockwise from the first axis direction while passing through the center of the first bump pad. The third length L₃ is along a third axis direction that is rotated 45 degrees clockwise from the first axis direction while passing through the center of the first bump pad. The second shape has the first length L₁ shorter than a major axis length L_{A} of the first connector parallel to the second axis direction and a major axis length L_{B} of the first connector parallel to the third axis direction, the second shape being different from the first shape. The third shape has a sum of a surface area of the first connector in the first area rotated 45 degrees counterclockwise to 135 degrees counterclockwise from the first axis direction and a surface area of the first connector in a third area rotated 45 degrees clockwise to 135 degrees clockwise from the first axis direction greater than a sum of a surface area of the first connector in the second area rotated 135 degrees counterclockwise to 225 degrees counterclockwise from the first axis direction and a surface area of the first connector in a fourth area rotated 45 degrees clockwise or 45 degrees counterclockwise from the first axis direction. The third shape is different from the first shape and the second shape.

According to some example embodiments, a semiconductor device includes a substrate including a first area extending from an edge toward a center of the substrate and a second area that is an area of the substrate excluding the first area, a first substrate pad on the first area and a second substrate pad on the second area, a substrate insulation layer surrounding at least a portion of each of the first substrate pad and the second substrate pad, a passivation layer on the substrate insulation layer, a first bump pad on the passivation layer, electrically connected to the first substrate pad, and including a first solder bump, and a second bump pad on the passivation layer, electrically connected to the second substrate pad, and including a second solder bump. The first bump pad includes a first connector that is recessed toward the first area, and the second bump pad includes a second connector that is recessed toward the second area. The first connector, when viewed in a first direction perpendicular to a surface of the substrate, has a shape including at least one of a first shape, a second shape, and a third shape. The first shape has a first length L₁ shorter than a second length L₂ and a third length L₃. The first length L₁ is along a first axis direction passing through a center of the first bump pad toward a center of the substrate. The second length L₂ is along a second axis direction that is rotated 45 degrees counterclockwise from the first axis direction while passing through the center of the first bump pad. The third length L₃ being is a third axis direction that is rotated 45 degrees clockwise from the first axis direction while passing through the center of the first bump pad. The second shape has the first length L₁ shorter than a major axis length L_{A} of the first connector parallel to the second axis direction and a major axis length L_{B} of the first connector parallel to the third axis direction. The second shape is different from the first shape. The third shape has a sum of a surface area of the first connector in the first area rotated 45 degrees counterclockwise to 135 degrees counterclockwise from the first axis direction and a surface area of the first connector in a third area rotated 45 degrees clockwise to 135 degrees clockwise from the first axis direction greater than a sum of a surface area of the first connector in the second area rotated 135 degrees counterclockwise to 225 degrees counterclockwise from the first axis direction and a surface area of the first connector in a fourth area rotated 45 degrees clockwise or 45 degrees counterclockwise from the first axis direction. The third shape is different from the first shape and the second shape. The semiconductor device includes an arrangement in which at least two first bump pads adjacent to each other among a plurality of first bump pads are parallel to the surface of the substrate, are spaced apart from each other in a second direction which intersects the first direction, and are spaced apart from each other in a third direction that is parallel to the surface of the substrate and intersects with the second direction. With respect to at least two first bump pads adjacent to each other among the plurality of first bump pads, the semiconductor device includes the first connector, the second connector, and a third connector. When viewed from the first direction, the first connector and the second connector are spaced apart from each other in the second direction and the first connector and the third connector are spaced apart from each other in the third direction, and the third connector has a shape that is same as a shape of the first connector and is rotated with respect to the first connector by a rotation angle. The rotation angle is less than 90 degrees. When viewed from the first direction, a surface area of the shape of the first connector is a same as a surface area of a shape of the second connector, or the surface area of the shape of the first connector is larger than the surface area of the shape of the second connector.

These and other example embodiments are discussed below in the detailed description and with reference to the accompanying drawings.

According to some example embodiments, a semiconductor device reduces defects occurring in solder bumps when the degree of expansion and contraction varies depending on the difference in coefficient of expansion.

Technical effects of the present disclosure are not limited to those described above, and other technical effects may be made apparent to those skilled in the art from the following description.

### BRIEF DESCRIPTION OF THE DRAWINGS

These and/or other aspects, features, and advantages of the example embodiments will become apparent and more readily appreciated from the following description of example embodiments, taken in conjunction with the accompanying drawings of which:

FIG. 1 is a cross-sectional diagram illustrating a semiconductor device according to some example embodiments.

FIG. 2 is a plan view of the bump pad and the connector of the semiconductor device of FIG. 1 having a first shape, according to some example embodiments.

FIG. 3 is a plan view illustrating a bump pad and a connector of the semiconductor device having a second shape, according to some example embodiments.

FIGS. 4, 5, and 6 illustrate the bump pad and the connector of the semiconductor device having a third shape, according to some example embodiments.

FIG. 7 is a cross-sectional diagram illustrating a semiconductor device according to some example embodiments.

FIG. 8 is a layout diagram of a semiconductor device according to some example embodiments.

FIG. 9 is a cross-sectional diagram illustrating a semiconductor device according to some example embodiments, and illustrates a portion P of FIG. 8.

FIG. 10 is a cross-sectional diagram illustrating a semiconductor device according to some example embodiments, and illustrates a portion P of FIG. 8.

FIG. 11 is an enlarged view of the portion P of FIG. 8 illustrating bump pads and connectors of the semiconductor device, according to some example embodiments.

FIG. 12 is an enlarged view of the portion P of FIG. 8 illustrating bump pads and connectors of the semiconductor device, according to some example embodiments.

FIG. 13 is an enlarged view of the portion P of FIG. 8 illustrating bump pads and connectors of the semiconductor device, according to some example embodiments.

FIG. 14 is an enlarged view of the portion P of FIG. 8 illustrating bump pads and connectors of the semiconductor device, according to some example embodiments.

FIG. 15 is an enlarged view of the portion P of FIG. 8 illustrating bump pads and connectors of the semiconductor device, according to some example embodiments.

FIG. 16 is an enlarged view of the portion P of FIG. 8 illustrating bump pads and connectors of the semiconductor device, according to some example embodiments.

FIG. 17 is a cross-sectional diagram schematically illustrating the semiconductor device 10, according to some example embodiments, and illustrates a portion Q of FIG. 8.

FIG. 18 illustrates bump pads and connectors of the semiconductor device, according to some example embodiments, and is an enlarged view of the portion Q of FIG. 8.

FIG. 19 is a cross-sectional diagram schematically illustrating the semiconductor device, according to some example embodiments, and illustrates a portion R of FIG. 8.

FIG. 20 illustrates bump pads and connectors of the semiconductor device, according to some example embodiments, and is an enlarged view of the portion R of FIG. 8.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with the technical idea of the example embodiments based on the understanding that the inventor may appropriately define the concept of terms in order to describe the example embodiments in the manner the inventor desires. The example embodiments described in this specification and the configurations shown in the drawings are example embodiments of the present disclosure, and may not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform the same or a similar function. For convenience of description and understanding, different example embodiments may be described using the same reference numerals or symbols. In other words, even if a component or an element having the same reference numeral is shown in multiple drawings, the multiple drawings may not all represent one example embodiment.

In the present disclosure, when an element is described as being “directly on,” “adjacent to” or “in contact with” another element, the element may be understood as being in direct contact with or connected to the another element, and it may be understood that there is no other element between the two.

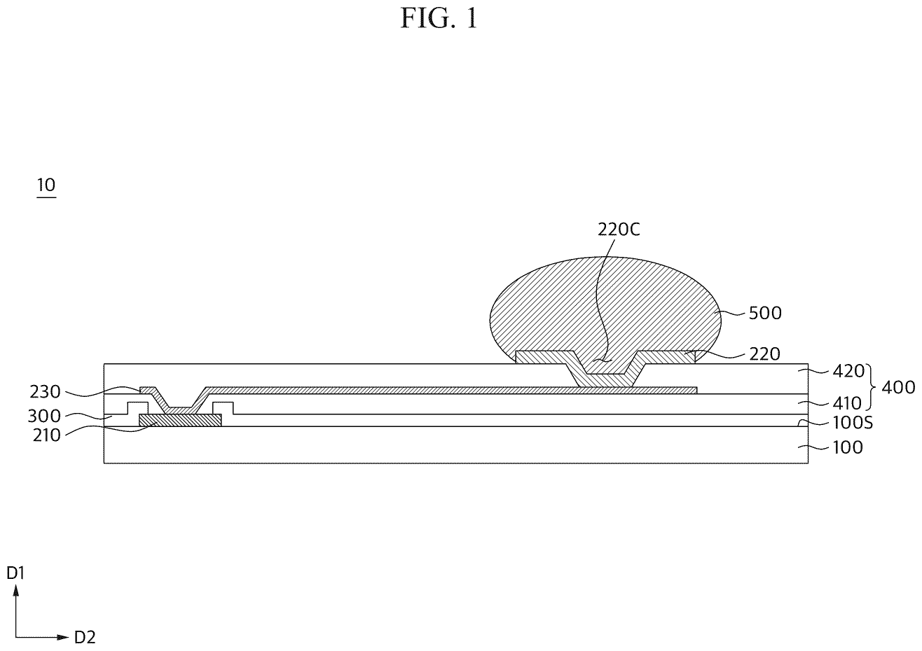

Further, in the present disclosure, when an element is described as being “on top of” another element, it may be understood as existing above the vertical direction, for example, as being above the +D1 direction in the drawing (FIG. 1), and the two elements may be in direct contact or connected, but it may also be understood that another element exists between the two. The same is applied even when an element is described as being “above” another element in the present disclosure.

Further, in the present disclosure, when an element is described as being “underneath” another element, it may be understood as existing below based on the vertical direction, for example, being further below based on the negative (−ve) D1 direction in the drawing (e.g., FIG. 1), and the two elements may be in direct contact or connected, but it may also be understood that another element exists between the two. The same is applied even when an element is described as being “beneath”another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side, and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

The properties described in the present disclosure may be measured in a room temperature and pressure environment unless specifically limited. In the present disclosure, as the natural temperature without any artificial manipulation, the room temperature can be 10° C. to 30° C., 20° C. to 28° C. or 22° C. to 26° C. In some example embodiments, the room temperature can be 25° C. In some example embodiments, as a natural pressure without any artificial manipulation, the pressure may be between 700 mmHg and 800 mmHg or between 720 mmHg and 780 mmHg, and in some example embodiments the pressure may be 760 mmHg.

The drawings illustrated in the present disclosure are according to mere example embodiments, and the ratio of the width, the length, and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the +(positive) direction, and the direction opposite to the direction indicated by the arrow (rotated by 180 degrees) may be the −(negative) direction.

FIG. 1 is a cross-sectional diagram illustrating a semiconductor device 10 according to some example embodiments. In some example embodiments, the semiconductor device 10 may include a substrate 100, a substrate pad 210, a substrate insulation layer 300, a passivation layer 400 and a bump pad 220.

In some example embodiments, the first direction D1 may indicate a direction perpendicular to a surface 100S of the substrate, the second direction D2 may indicate a direction that is parallel to the surface 100S of the substrate while intersecting the first direction D1, and the third direction D3 may indicate a direction that is parallel to the surface 100S of the substrate while intersecting with the first direction D1 and the second direction D2. In some example embodiments, referring to FIG. 1, the second direction D2 may be perpendicular to the first direction D1, and the third direction D3 may be perpendicular to the first direction D1 and the second direction D2.

In some example embodiments, the substrate 100 is not particularly limited, but may be a silicon substrate, a semiconductor compound substrate, a plastic substrate, a glass substrate, or a ceramic substrate. In some example embodiments, a package substrate may include an impurity region by doping, an electronic device such as a transistor, or a periphery circuit that selects and controls a memory cell.

In some example embodiments, the substrate pad 210 may be disposed on the substrate 100. In some example embodiments, the substrate pad 210 may be sized, shaped, or otherwise configured to protrude from the surface 100S of the substrate. In some example embodiments, the substrate pad 210 may be shaped to protrude from the surface 100S of the substrate toward the first direction D1, and the substrate pad 210 may extend in the second direction D2. In some example embodiments, there may be a plurality of substrate pads 210, and the plurality of substrate pads 210 may be arranged with a desired (or, alternatively, predetermined) spacing between each other. In some example embodiments, the plurality of substrate pads 210 may be arranged with a desired (or, alternatively, predetermined) spacing from each other along the second direction D2.

In some example embodiments, the substrate pad 210 may include a conductive material. In some example embodiments, the conductive material may be or include at least one or more of doped polysilicon, a metal, a conductive metal nitride, a conductive metal silicide, and a conductive metal oxide. In some example embodiments, the metal may include one or more of aluminum (Al), copper (Cu), titanium (Ti), tantalum (Ta), rubidium (Ru), tungsten (W), molybdenum (Mo), platinum (Pt), nickel (Ni), tin (Sn), lead (Pb), and cobalt (Co). In some example embodiments, the conductive metal nitride may include at least one or more of titanium aluminum nitride (TiAlN), tantalum silicon nitride (TaSiN) and rubidium titanium nitride (RuTiN). In some example embodiments, the conductive metal silicide may include at least one or more of titanium silicide (TiSi), tantalum silicide (TaSi), nickel silicide (NiSi) and cobalt silicide (CoSi). In some example embodiments, the conductive metal oxide may include at least one or more of iridium oxide (IrOₓ) and rubidium oxide (RuOₓ).

In some example embodiments, the substrate insulation layer 300 may surround at least a portion of the substrate pad 210. In some example embodiments, the substrate insulation layer 300 may surround at least a portion of the substrate pad 210, and may be disposed on the substrate 100. In some example embodiments, the substrate insulation layer 300 may be disposed on the surface 100S of the substrate 100 and may extend in the first direction D1 and the second direction D2. In some example embodiments, the substrate insulation layer 300 may expose at least a portion of the substrate pad 210. In some example embodiments, the substrate insulation layer 300 may expose a portion of the substrate pad 210 while burying or overlapping one or more other portions of the substrate pad 210. In some example embodiments, the substrate insulation layer 300 may include an insulating material.

In some example embodiments, the insulating material is not limited to any particular material, and may include one or more materials selected from, for example, silicon oxide, silicon nitride and silicon oxynitride.

In some example embodiments, the passivation layer 400 may be disposed on the substrate insulation layer 300. In some example embodiments, the passivation layer 400 may be disposed on the substrate insulation layer 300 in the first direction D1 and may extend in the first direction D1 and the second direction D2. In some example embodiments, the passivation layer 400 may surround at least a portion of the substrate pad 210 exposed by the substrate insulation layer 300. In some example embodiments, the passivation layer 400 may include an insulating material.

In some example embodiments, the passivation layer 400 may include a plurality of layers. In some example embodiments, the passivation layer 400 may include a first passivation layer 410 in contact (e.g., direct contact) with the substrate insulation layer 300 at least in some (e.g., one or more) areas, and a second passivation layer 420 disposed on the first passivation layer 410 and in contact (e.g., direct contact) with the first passivation layer 410 at least in some (e.g., one or more) areas. In some example embodiments, the first passivation layer 410 may be disposed on the substrate insulation layer 300 in the first direction D1, and the second passivation layer 420 may be placed on the first passivation layer 410 in the first direction D1. The first passivation layer 410 and the second passivation layer 420 may extend in the first direction D1 and the second direction D2.

In some example embodiments, the bump pad 220 may be placed or formed on the passivation layer 400. In some example embodiments, the bump pad 220 may be placed on the passivation layer 400 in the first direction D1. In some example embodiments, the bump pad 220 may be at least partially exposed by the passivation layer 400. In other words, the passivation layer 400 may not overlap portions of the bump pad 220 or may not contact portion of the passivation layer 400. In some example embodiments, the bump pad 220 may be electrically connected to the substrate pad 210. In some example embodiments, a solder bump 500 may be mounted or formed on the bump pad 220. In some example embodiments, the bump pad 220 may include a conductive material. In some example embodiments, the solder bump 500 may include one or more of lead (Pb) and tin (Sn).

In some example embodiments, the bump pad 220 may include a connector 220C (or a connector portion) that may be a recessed portion that extends toward the substrate 100. In some example embodiments, a portion of the bump pad 220 may be recessed from the surface of the passivation layer 400 toward the substrate 100 (in other words, in the negative D1 direction), and the recessed area may be referred to as the connector 220C. In some example embodiments, the connector 220C may include an inclined side surface, and the inclined side surface may have an angle of greater than or equal to 90 degrees and less than 180 degrees with respect to the surface of the passivation layer 400. However, example embodiments are not limited thereto.

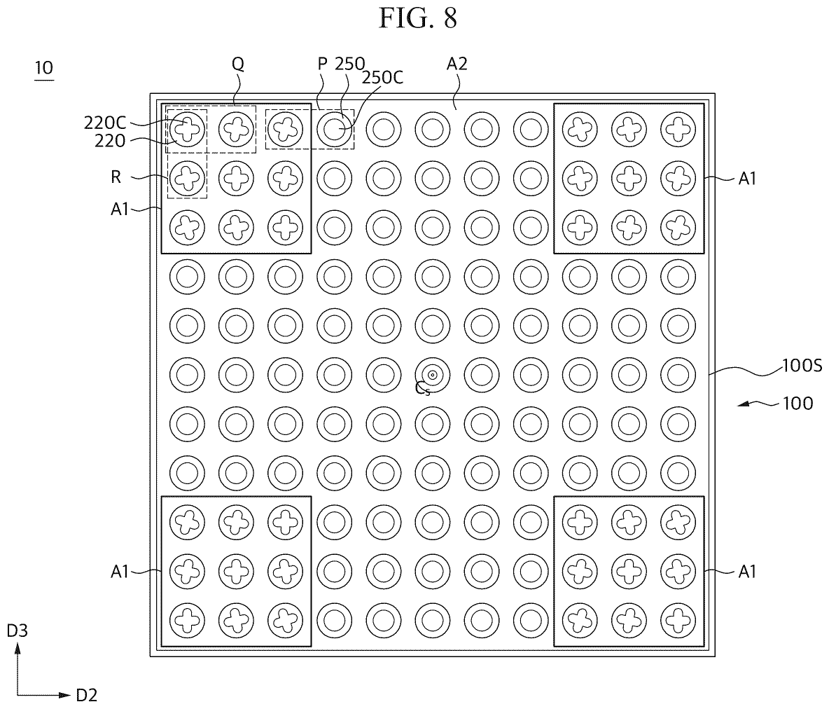

In some example embodiments, as described above, the degree of expansion and contraction may vary due to differences in the CTE, which may apply stress to the solder bump 500, and the stress may be applied radially from the center of the substrate C_{S} (see FIG. 8). The stress caused by the difference in the CTE may decrease as the length of the connector 220C decreases based on the direction in which the stress is applied. However, as the length of the connector 220C is shortened, when viewed from the first direction D1 (e.g., in a plan view), as the surface area of the connector 220C decreases, electro-migration (EM) may increase. In some example embodiments, by reducing the stress caused by the difference in the CTE through the shape of the connector 220C, when viewed from the first direction D1, it may be possible to reduce or limit defects occurring at the solder bump 500 while reducing, limiting, or preventing occurrence of the EM.

In some example embodiments, when viewed from the first direction D1, the connector 220C may have a shape selected from a first shape, a second shape and a third shape as below. Through this, the semiconductor device 10 may reduce defects occurring in the solder bump 500 by reducing stress caused by differences in the CTE, while reducing, lowering, or preventing EM.

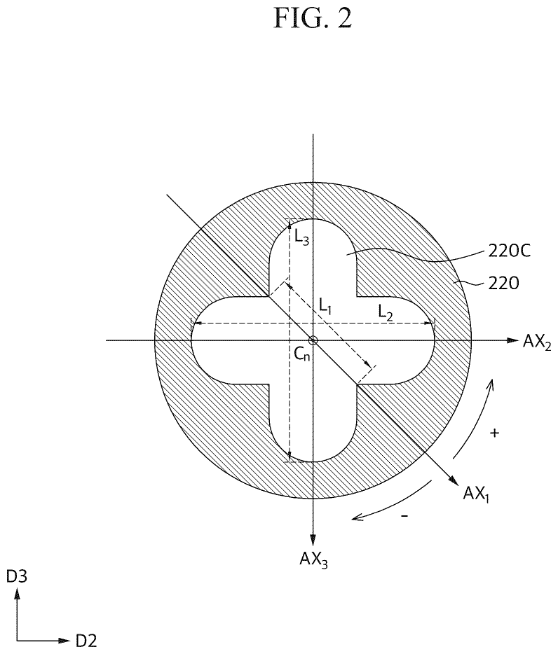

FIG. 2 is a plan view of the bump pad 220 and the connector 220C of the semiconductor device 10 of FIG. 1 having a first shape, according to some example embodiments. In some example embodiments, the connector 220C may have the first shape in which the first length L₁, which may be the length along the first axis direction AX₁ passing through the center Cn of the bump pad 220 and toward the center C_{S} of the substrate (see FIG. 8) when viewed from the first direction D1, is shorter than the second length L₂, which may be the length along the second axis direction AX₂ rotated 45 degrees counterclockwise from the first axis direction AX₁ while passing through the center Cn of the bump pad, and the third length L₃, which may be the length along the third axis direction AX₃ rotated 45 degrees clockwise from the first axis direction AX₁ while passing through the center Cn of the bump pad. In some example embodiments, the stress generated due to the difference in the CTE described above may act along the first axis direction AX₁. Referring to FIG. 2, in the connector 220C of the first shape, the first length L₁ may be shorter than the second length L₂ and the third length L₃. In some example embodiments, the first shape may be a point-symmetrical shape (or, alternatively, may have a point-symmetry) based on the center Cn of the bump pad. In some example embodiments, the first shape may be a line-symmetrical shape (or, alternatively, may have a line-symmetry) with respect to at least one of the first axis direction AX₁, the second axis direction AX₂ and the third axis direction AX₃. In some example embodiments, the first shape may be a point-symmetrical shape based on the center Cn of the bump pad, and may be a line-symmetrical shape based on at least one of the first axis direction AX₁, the second axis direction AX₂, and the third axis direction AX₃. In some example embodiments, the first shape may be a line-symmetrical shape with respect to all of the first axis direction AX₁, the second axis direction AX₂ and the third axis direction AX₃. Through this, the semiconductor device 10 may reduce the stress caused by the difference in the CTE, thereby reducing defects occurring in the solder bump 500 while reducing or preventing occurrence of the EM. For example, the first shape may be a cross shape (or ‘+’ shape) as illustrated in FIG. 2. The first shape may be a point-symmetrical shape based on the center Cn of the bump pad, and may also be a line-symmetrical shape based on the first axis direction AX₁, the second axis direction AX₂ and third axis direction AX₃.

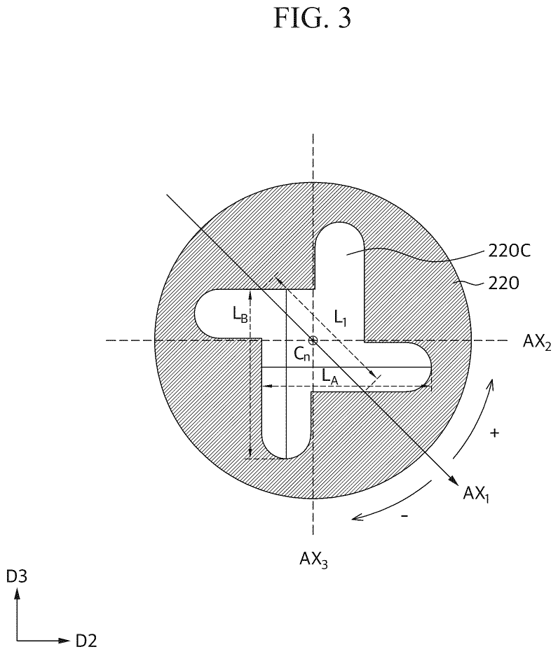

FIG. 3 is a plan view illustrating a bump pad 220 and a connector 220C of the semiconductor device 10 having a second shape, according to some example embodiments. In some example embodiments, the connector 220C may have a second shape that is different from the first shape. In the second shape, the first length L₁ may be shorter than the major axis length L_{A} of the connector 220C parallel to the second axis direction AX₂ and the major axis length L_{B} of the connector 220C parallel to the third axis direction AX₃. Referring to FIG. 3, the second shape of the connector 220C may be the shape of a pinwheel having 4 radially extending arms or vanes. Each major axis length L_{A} and the major axis length L_{B} may be defined as the distance between a radially distal end of an arm and an outer edge of a diametrically adjacent arm. Referring to FIG. 3, the connector 220C may have the second shape in which the first length L₁ may be shorter than the major axis length L_{A} of the connector 220C that is parallel to the second axis direction AX₂ and the major axis length L_{B} of the connector 220C that is parallel to the third axis direction AX₃. In some example embodiments, the second shape may be a point-symmetrical shape with respect to the center Cn of the bump pad. In some example embodiments, in the second shape, the major axis length L_{A} of the connector 220C that is parallel to the second axis direction AX₂ and the major axis length L_{B} of the connector 220C that is parallel to the third axis direction AX₃ may be longer than one or more of the lengths along the second axis direction AX₂ passing through the center Cn of the bump pad and the lengths along the third axis direction AX₃ passing through the center Cn of the bump pad. The connector 220C of the second shape may reduce defects occurring in the solder bump 500 by distributing the stress generated due to the difference in the CTE through bending stress and torsion stress, while reducing or preventing occurrence of the EM. The second shape may be a point-symmetrical shape based on the center Cn of the bump pad, which may be different from the first shape.

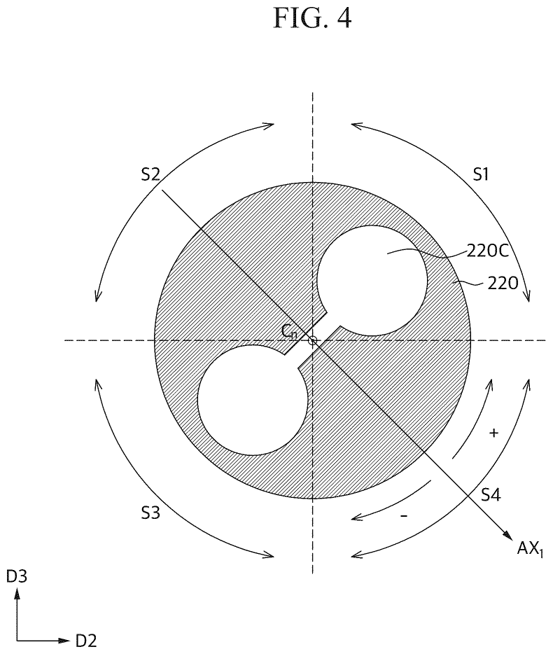

FIGS. 4, 5, and 6 illustrate the bump pad 220 and the connector 220C of the semiconductor device 10 having a third shape, according to some example embodiments. In some example embodiments, the connector 220C may have a third shape that is different from the first shape and the second shape, and in the third shape, the sum of a surface area of the connector 220C in a first area S1 rotated 45 degrees counterclockwise to 135 degrees counterclockwise in the first axis direction AX₁ and a surface area of the connector 220C in a third area S3 rotated 45 degrees clockwise to 135 degrees clockwise from the first axis direction AX₁ may be greater than the sum of a surface area of the connector 220C in a second area S2 rotated 135 degrees counterclockwise to 225 degrees counterclockwise from the first axis direction AX₁ and a surface area of the connector 220C in a fourth area S4 rotated 45 degrees clockwise or 45 degrees counterclockwise from the first axis direction AX₁. Stated otherwise, referring to circular shape of the bump pad 220 in FIG. 4, the first area S1 may be in the first quadrant, the second area S2 may be in the second quadrant, the third area S3 may be in the third quadrant S3, and the fourth area S4 may be in the fourth quadrant. The sum of the surface area of the connector 220C in the first area S1 and the surface area of the connector 220C in the third area S3 may be greater than the sum of the surface area of the connector 220C in the second area S2 and the surface area of the connector 220C in the fourth area S4. Referring to FIG. 4, the connector 220C may have a dumbbell shape symmetrically arranged in the first area S1 and the third area S3, and the connector 220C may be absent in the second area S2 and the fourth area S4. Referring to FIG. 4, the third shape may have the same shape (e.g., circular shape) in the first area S1 and the same shape (e.g., circular shape) in the third area S3. The third shape may be a point-symmetrical shape based on the center Cn of the bump pad, and may be a line-symmetrical shape based on the first axis direction AX₁.

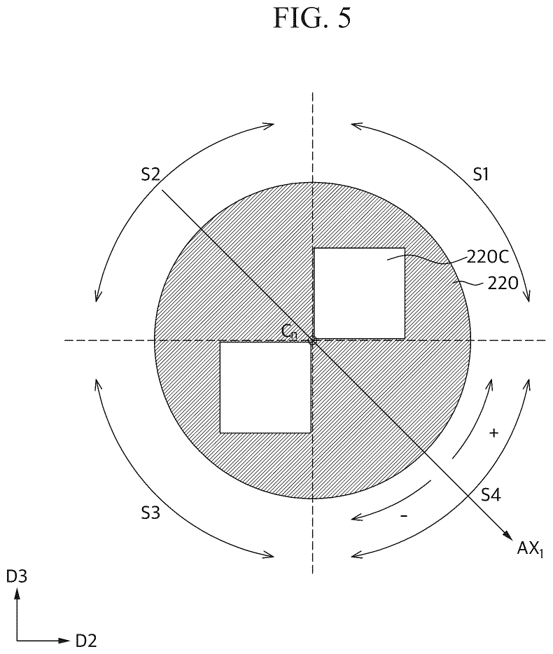

Referring to FIG. 5, in the third shape, the connector 220C may be present or arranged in the first area S1 and the third area S3, and the connector 220C may not present in the second area S2 and the fourth area S4. As illustrated in FIG. 5, the connector 220C may be shaped as two squares diametrically (or diagonally) contacting each other at the center Cn of the bump pad.

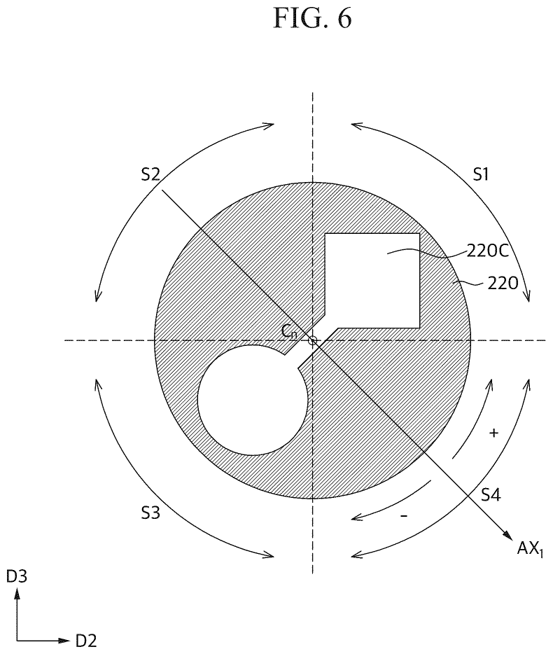

Referring to FIG. 6, the connector 220C having the third shape may have different shapes in the first area S1 and the third area S3. For example, as illustrated in FIG. 6, the connector 220C may be dumbbell-type shape having a square shaped end in first area S1 and a circular shaped end in the third area S3. The semiconductor device 10 may lower or reduce defects occurring in the solder bump 500 by reducing or lowering stress caused by differences in the CTE, while reducing or preventing occurrence of the EM.

Referring to FIG. 1, in some example embodiments, the substrate pad 210 and the bump pad 220 may not be in contact. In some example embodiments, when viewed from the first direction D1 (e.g., in a plan view), the substrate pad 210 and the bump pad 220 may not vertically overlap each other, for example the substrate pad 210 may not be directly below the bump pad 220, but example embodiments are not limited thereto. In some example embodiments, the semiconductor device 10 may include a redistribution line (RDL) 230 electrically connected to the substrate pad 210 and the bump pad 220. In some example embodiments, the RDL 230 may electrically connect non-contacting substrate pad 210 and the bump pad 220 to each other. In some example embodiments, the RDL 230 may be placed within the passivation layer 400. In some example embodiments, the RDL 230 may be placed on the first passivation layer 410, and may be placed on the first passivation layer 410 in the first direction D1. In some example embodiments, the RDL 230 may be at least partially exposed by the first passivation layer 410. In other words, the first passivation layer 410 may not contact one or more portions of the RDL 230. In some example embodiments, the second passivation layer 420 may surround or contact at least a portion of the RDL 230 exposed by the first passivation layer 410. In some example embodiments, the RDL 230 may include a conductive material.

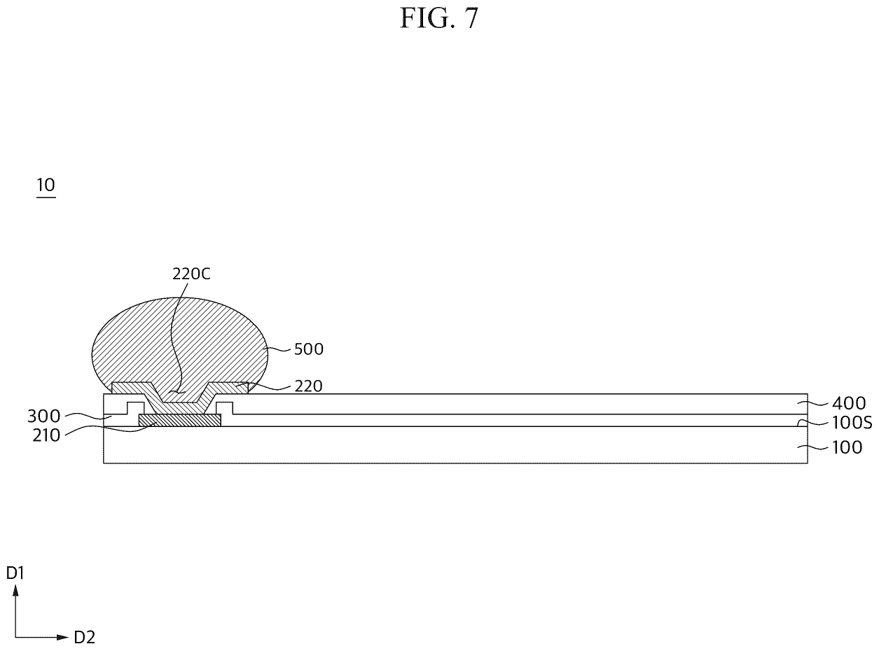

FIG. 7 is a cross-sectional diagram illustrating the semiconductor device 10, according to some example embodiments. In some example embodiments, the substrate pad 210 and the bump pad 220 may be in contact, for example, in direct contact. In some example embodiments, when viewed from the first direction D1, the substrate pad 210 and the bump pad 220 may vertically overlap each other at least in some portions. For example, the substrate pad 210 may be directly below the bump pad 220. However, example embodiments are not limited thereto. In some example embodiments, the passivation layer 400 may contact at least a portion of the substrate pad 210 and at least a portion of the bump pad 220.

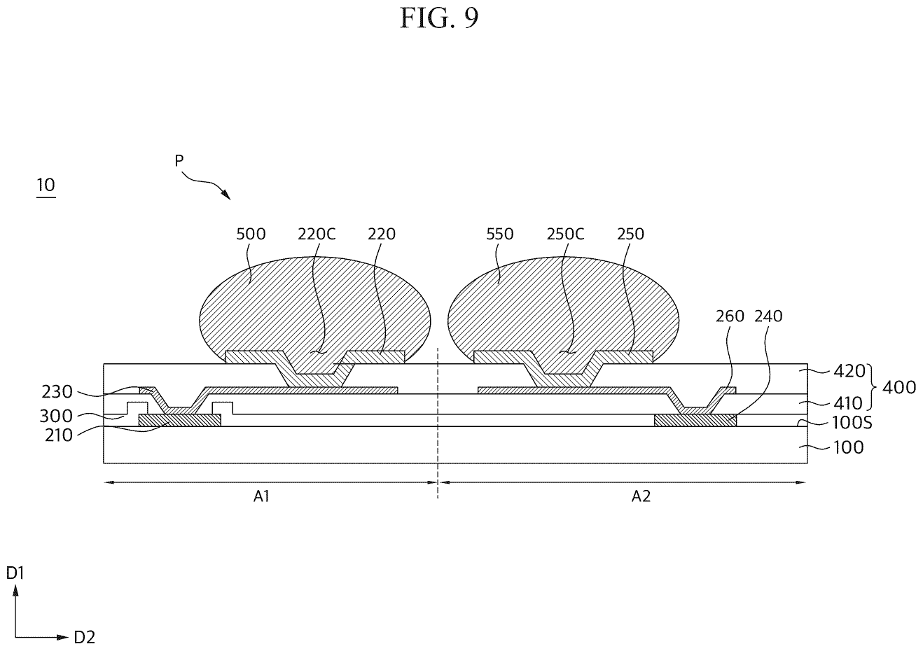

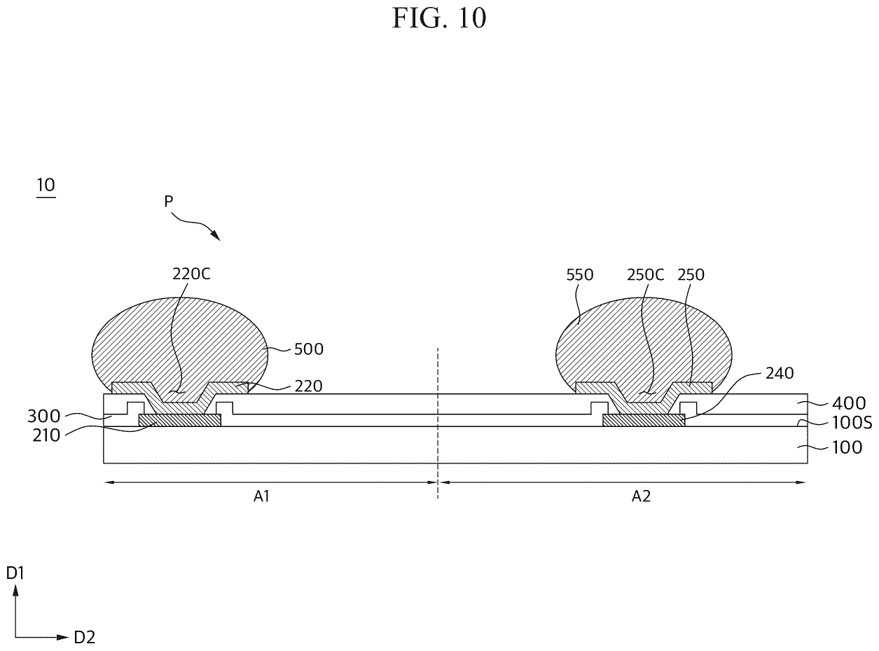

FIG. 8 is a layout diagram of the semiconductor device 10, according to some example embodiments. FIG. 9 is a cross-sectional diagram schematically illustrating the semiconductor device 10, according to some example embodiments, and illustrates a portion P of FIG. 8. FIG. 10 is a cross-sectional diagram schematically illustrating the semiconductor device 10, according to some example embodiments, and illustrates a portion P of FIG. 8.

In some example embodiments, the substrate 100 may include a first area A1, which is a region extending from at least a portion of an edge toward a center C_{S} of the substrate, and a second area A2 that is an area other than the first area A1. Stated otherwise, the first area A1 is defined adjacent or proximate each corner of the substrate 100. The first area A1 may be square-shaped, as illustrated in FIG. 8, or may have any other desired shape.

In some example embodiments, the semiconductor device 10 may include a first substrate pad 210 disposed on the first area A1 and a second substrate pad 240 disposed on the second area A2. The first substrate pad 210 may be identical to the substrate pad 210 described with reference to FIG. 1 to FIG. 7. The second substrate pad 240 may be the same as or similar in some respects to the substrate pad 210 described with reference to FIG. 1 to FIG. 7, and may be best understood with reference thereto, and a description thereof is not repeated for the sake of brevity. In some example embodiments, the first substrate pad 210 and the second substrate pad 240 may be arranged with a desired (or, alternatively, predetermined) gap between them. For example, the first substrate pad 210 and the second substrate pad 240 may be arranged with a desired (or, alternatively, predetermined) gap from each other along the second direction D2.

In some example embodiments, the substrate insulation layer 300 may surround at least a portion of each of the first substrate pad 210 and the second substrate pad 240. The substrate insulation layer 300 may be same as or similar in some respects to the substrate insulation layer 300 in FIG. 1 to FIG. 7, and therefore may be best understood with reference thereto. In some example embodiments, the passivation layer 400 may be disposed on the substrate insulation layer 300. The passivation layer 400 may be same as or similar in some respects to the passivation layer 400 in FIG. 1 to FIG. 7, and therefore may be best understood with reference thereto.

In some example embodiments, the semiconductor device 10 may include a first bump pad 220 and a second bump pad 250. In some example embodiments, the first bump pad 220 may be same as or similar in some respects to the first bump pad 220 described with reference to FIG. 1 to FIG. 7. In some example embodiments, the first bump pad 220 may be electrically connected to the first substrate pad 210. In some example embodiments, a first solder bump 500 may be mounted or formed on the first bump pad 220. In some example embodiments, the first solder bump 500 may be same as or similar in some respects to the solder bump 500 described with reference to FIG. 1 to FIG. 7. In some example embodiments, the second bump pad 250 may be same as or similar in some respects to the bump pad 220 described with reference to FIG. 1 to FIG. 7, and therefore may be best understood with reference thereto. In some example embodiments, the second bump pad 250 may be electrically connected to the second substrate pad 240. In some example embodiments, a second solder bump 550 may be mounted on the second bump pad 250. In some example embodiments, the second solder bump 550 may be same as or similar in some respects to the solder bump 500 described with reference to FIG. 1 to FIG. 7, and therefore may be best understood with reference thereto. In some example embodiments, the semiconductor device 10 may include a plurality of first bump pads 220. In some example embodiments, there may be a plurality of second bump pads 250.

In some example embodiments, the first bump pad 220 may include the first connector 220C recessed toward the first area A1 of the substrate 100. In some example embodiments, the first connector 220C may be same as or similar in some respects to the first connector 220C described with reference to FIG. 1 to FIG. 7. In some example embodiments, the second bump pad 250 may include a second connector 250C recessed toward the second area A2 of the substrate 100. In some example embodiments, the second connector 250C may be same as or similar in some respects to the first connector 220C described with reference to FIG. 1 to FIG. 7, and may be best understood with reference thereto.

In some example embodiments, the first bump pad 220 may include the first connector 220C recessed toward the first area A1 of the substrate 100. In some example embodiments, a portion of the first bump pad 220 may be recessed from the surface of the passivation layer 400 toward the first area A1 of the substrate 100 (in other words, the negative D1 direction), and the recessed area may be referred to as the first connector 220C. In some example embodiments, the first connector 220C may include an inclined surface. The inclined surface may have an angle greater than or equal to 90 degrees and less than or equal to 180 degrees with respect to the surface of the passivation layer 400, but is not limited thereto.

In some example embodiments, the second bump pad 250 may include the second connector 250C recessed toward the second area A2 of the substrate 100. In some example embodiments, a portion of the second bump pad 250 may be recessed from the surface of the passivation layer 400 toward the second area A2 of the substrate 100 (in other words, the negative D1 direction), and the recessed area may be referred to as the second connector 250C. In some example embodiments, the second connector 250C may include an inclined surface. The inclined surface may have an angle greater than or equal to 90 degrees and less than or equal to 180 degrees with respect to the surface of the passivation layer 400, but is not limited thereto.

In some example embodiments, when viewed from the first direction D1 (e.g., in a plan view), the surface area of the shape of the first connector 220C may be equal to the surface area of the shape of the second connector 250C, or may be larger than the surface area of the shape of the second connector 250C. The semiconductor device 10 may reduce or lower defects occurring at the solder bump 500 while reducing or preventing further occurrence of the EM.

Referring to FIG. 9, in some example embodiments, the first substrate pad 210 and the first bump pad 220 may not be in contact. In some example embodiments, when viewed from the first direction D1, the first substrate pad 210 and the first bump pad 220 may not vertically overlap each other, for example, first substrate pad 210 may not be directly below the first bump pad 220. However, example embodiments are not limited thereto. In some example embodiments, the semiconductor device 10 may include a first RDL 230 electrically connected to the first substrate pad 210 and the first bump pad 220. In some example embodiments, the first RDL 230 may electrically connect a non-contacting first substrate pad 210 and the first bump pad 220 to each other. In some example embodiments, the first RDL 230 may be placed within the passivation layer 400. In some example embodiments, the first RDL 230 may be placed on the first passivation layer 410, and may be placed on the first passivation layer 410 in the first direction D1. In some example embodiments, the first RDL 230 may be at least partially exposed by (e.g., not contacted by) the first passivation layer 410. In some example embodiments, the second passivation layer 420 may surround at least a portion of the first RDL 230 exposed by the first passivation layer 410. In some example embodiments, the first RDL 230 may include a conductive material. In some example embodiments, the second substrate pad 240 and the second bump pad 250 may not be in contact. In some example embodiments, when viewed from the first direction D1, the second substrate pad 240 and the second bump pad 250 may not overlap each other, for example, may not directly overlap each other. However, example embodiments are not limited thereto. In some example embodiments, the semiconductor device 10 may include a second RDL 260 electrically connected to the second substrate pad 240 and the second bump pad 250. In some example embodiments, the second RDL 260 may electrically connect the non-contacted first substrate pad 210 and the first bump pad 220 to each other. In some example embodiments, the second RDL 260 may be placed within the passivation layer 400. In some example embodiments, the second RDL 260 may be placed on the first passivation layer 410, and may be placed on the first passivation layer 410 in the first direction D1. In some example embodiments, the second RDL 260 may be at least partially exposed by the first passivation layer 410. In some example embodiments, the second passivation layer 420 may surround at least a portion of the second RDL 260 exposed by the first passivation layer 410. In some example embodiments, the second RDL 260 may include a conductive material.

Referring to FIG. 10, in some example embodiments, the first substrate pad 210 and the first bump pad 220 may be in contact. In some example embodiments, when viewed from the first direction D1 (e.g., in a plan view), the first substrate pad 210 and the first bump pad 220 may overlap each other, for example, directly overlap each other, at least in some area. However, example embodiments are not limited thereto. In some example embodiments, the passivation layer 400 may contact at least a portion of the first substrate pad 210 and at least a portion of the first bump pad 220. In some example embodiments, the second substrate pad 240 and the second bump pad 250 may be in contact. In some example embodiments, when viewed from the first direction D1, the second substrate pad 240 and the second bump pad 250 may overlap each other, for example, directly overlap each other, at least in some area. However, example embodiments are not limited thereto. In some example embodiments, the passivation layer 400 may contact at least a portion of the second substrate pad 240 and at least a portion of the second bump pad 250.

In some example embodiments, when viewed from the first direction D1 (e.g., in a plan view), the first connector 220C may have a shape selected from a first shape, a second shape and a third shape, as below. The semiconductor device 10 may reduce or limit the stress caused by the difference in the CTE, thereby reducing the defects occurring in the first solder bump 500, while reducing or preventing occurrence of the EM. In some example embodiments, the semiconductor device 10 may include a plurality of first bump pads 220. In some example embodiments, the first connectors 220C of at least one of a plurality of first bump pads 220 may have a shape selected from a first shape, a second shape and a third shape, when viewed from the first direction D1 (e.g., in a plan view), as below. In some example embodiments, the first connector 220C of the plurality of first bump pads 220 may each independently have a shape selected from a first shape, a second shape and a third shape, when viewed from the first direction D1 (e.g., in a plan view), as below.

In some example embodiments, some of the plurality of first bump pads 220 that are adjacent to each other may be spaced apart from each other with respect to the second direction D2. Further, some of the plurality of first bump pads 220 that are adjacent to each other may be spaced apart from each other with respect to the third direction D3. In some example embodiments, in an arrangement structure, some of the plurality of first bump pads 220 that are adjacent to each other may be spaced apart from each other based on the second direction D2 and the third direction D3.

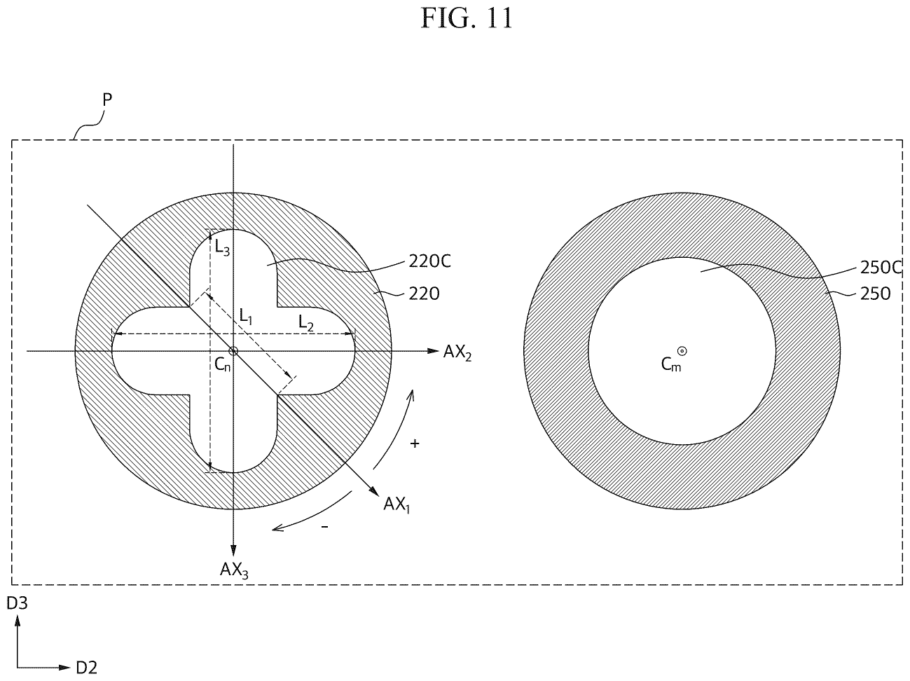

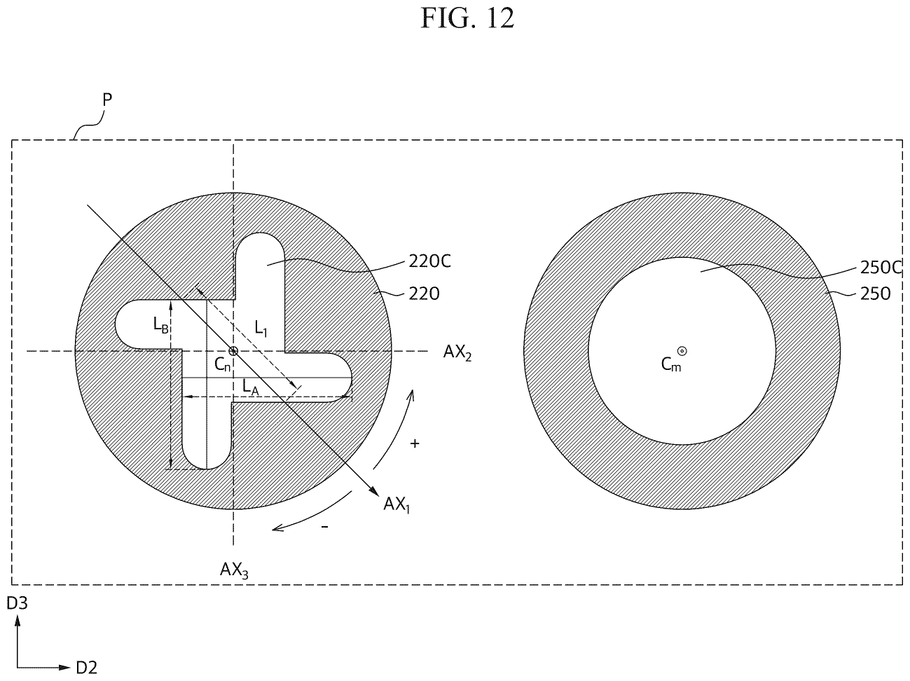

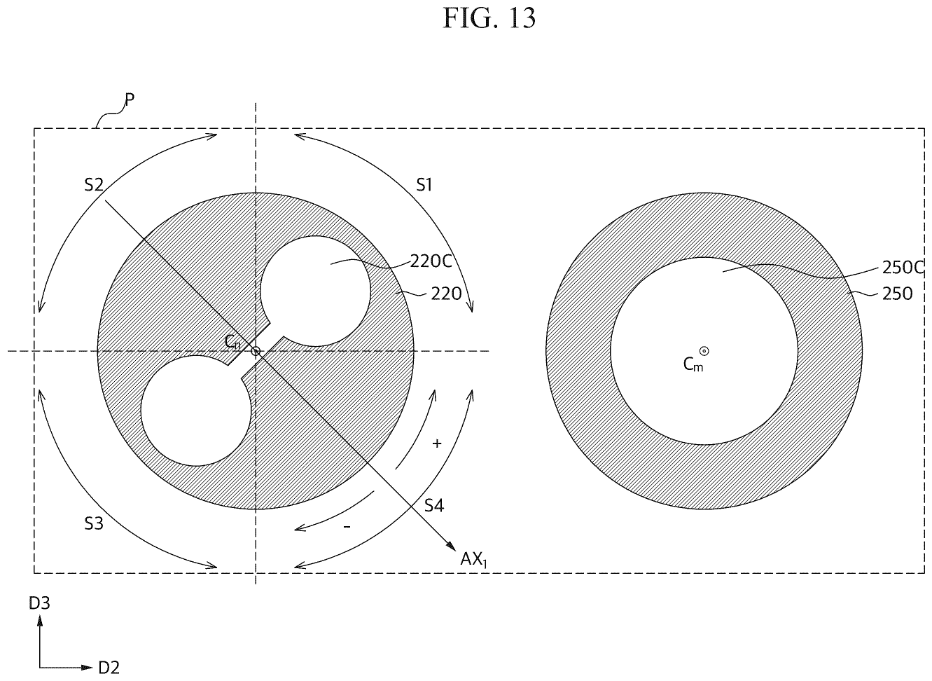

FIG. 11 is an enlarged view of the portion P of FIG. 8 illustrating bump pads (the first bump pad 220 and the second bump pad 250) and connectors (the first connector 220C and the second connector 250C) of the semiconductor device 10 according to some example embodiments and illustrates the first connector 220C having the first shape (FIG. 2) and the second connector 250C having the circular shape. FIG. 12 is an enlarged view of the portion P of FIG. 8 illustrating bump pads (the first bump pad 220 and the second bump pad 250) and connectors (the first connector 220C and the second connector 250C) of the semiconductor device 10, according to some example embodiments, and illustrates the first connector 220C having the second shape (FIG. 3) and the second connector 250C having the circular shape. FIG. 13 is an enlarged view of the portion P of FIG. 8 illustrating bump pads (the first bump pad 220 and the second bump pad 250) and connectors (the first connector 220C and the second connector 250C) of the semiconductor device 10 according to some example embodiments, and illustrates the first connector 220C having the third shape (FIG. 4) and the second connector 250C having the circular shape.

In some example embodiments, the first connector 220C of the first bump pad 220 may have the first shape in which the first length L₁ is shorter than the second length L₂ and the third length L₃. The length may be along the first axis direction AX₁ toward the center C_{S} of the substrate, passing through the center Cn of the first bump pad when viewed from the first direction D1. The second length L₂ may be along the second axis direction AX₂ rotated 45 degrees counterclockwise from the first axis direction AX₁ while passing through the center Cn of the first bump pad. The third length L₃ may be along the third axis direction AX₃ rotated 45 degrees clockwise from the first axis direction AX₁ while passing through the center Cn of the first bump pad. In some example embodiments, the stress generated due to the difference in the CTE, as described above, may act along the first axis direction AX₁. Referring to FIG. 11, in the first connector 220C of the first shape, the first length L₁ may be shorter than the second length L₂ and the third length L₃. In some example embodiments, the first shape may be a point-symmetrical shape based on the center Cn of the first bump pad. In some example embodiments, the first shape may be a line-symmetrical shape with respect to at least one of the first axis direction AX₁, the second axis direction AX₂ and the third axis direction AX₃. In some example embodiments, the first shape may be a point-symmetrical shape based on the center Cn of the first bump pad and a line-symmetrical shape based on at least one of the first axis direction AX₁, the second axis direction AX₂ and the third axis direction AX_{3.} In some example embodiments, the first shape may be a line-symmetrical shape with respect to all of the first axis direction AX₁, the second axis direction AX₂ and the third axis direction AX_{3.} The semiconductor device 10 may reduce or lower the stress caused by the difference in the CTE, thereby lowering or reducing the defects occurring in the first solder bump 500, while reducing or preventing further occurrence of the EM.

In some example embodiments, the first connector 220C of the first bump pad 220 may have a second shape different from the first shape, and in the second shape, the first length L₁ may be shorter than the major axis length L_{A} of the first connector 220C parallel to the second axis direction AX₂ and the major axis length L_{B} of the first connector 220C parallel to the third axis direction AX₃. Referring to FIG. 12, the first connector 220C of the second shape may be different from the first shape, and the first length L₁ may be smaller than the major axis length L_{A} of the first connector 220C parallel to the second axis direction AX₂ and the major axis length L_{B} of first connector 220C parallel to third axis direction AX₃. In some example embodiments, the second shape may be a point-symmetrical shape with respect to the center Cn of the first bump pad. In some example embodiments, in the second shape, the major axis length L_{A} of the first connector 220C parallel to the second axis direction AX₂ and the major axis length L_{B} of the first connector 220C parallel to the third axis direction AX₃ may be longer than at least one of the length along the second axis direction AX₂ passing through the center Cn of the first bump pad and the length along the third axis direction AX₃ passing through the center Cn of the first bump pad. The first connector 220C of the second shape may reduce or lower defects occurring in the first solder bump 500 by distributing the stress generated due to the difference in the CTE through bending stress and torsion stress, while lowering, reducing, or preventing occurrence of the EM.

In some example embodiments, the first connector 220C of the first bump pad 220 may have a third shape that is different from the first shape and the second shape. In the third shape, the sum of the surface area of the first connector 220C in the first area S1 rotated 45 degrees counterclockwise to 135 degrees counterclockwise in the first axis direction AX₁ and the surface area of the first connector 220C in the third area S3 rotated 45 degrees clockwise to 135 degrees clockwise from the first axis direction AX₁ is greater than the sum of the surface area of the first connector 220C in the second area S2 rotated 135 degrees counterclockwise to 225 degrees counterclockwise from the first axis direction AX₁ and the surface area of the first connector 220C in the fourth area S4 rotated 45 degrees clockwise or 45 degrees counterclockwise from the first axis direction AX₁. The semiconductor device 10 may reduce the stress caused by the difference in the CTE, thereby reducing or lowering the defects occurring in the first solder bump 500, while reducing or preventing further occurrence of the EM. Referring to FIG. 13, the third shape may have the same or similar shape in the first area S1 and the same or similar shape in the third area S3. Here, the third shape may be a point-symmetrical shape based on the center Cn of the first bump pad, and may be a line-symmetrical shape based on the first axis direction AX₁.

In some example embodiments, the second connector 250C may be circular when viewed from the first direction D1. Here, when viewed from the first direction D1, the surface area of the shape of the first connector 220C may be the same as or similar to the surface area of the shape of the second connector 250C, or may be larger than the surface area of the shape of the second connector 250C. The semiconductor device 10 may reduce or lower defects occurring at the solder bump 500 while reducing or preventing further occurrence of the EM.

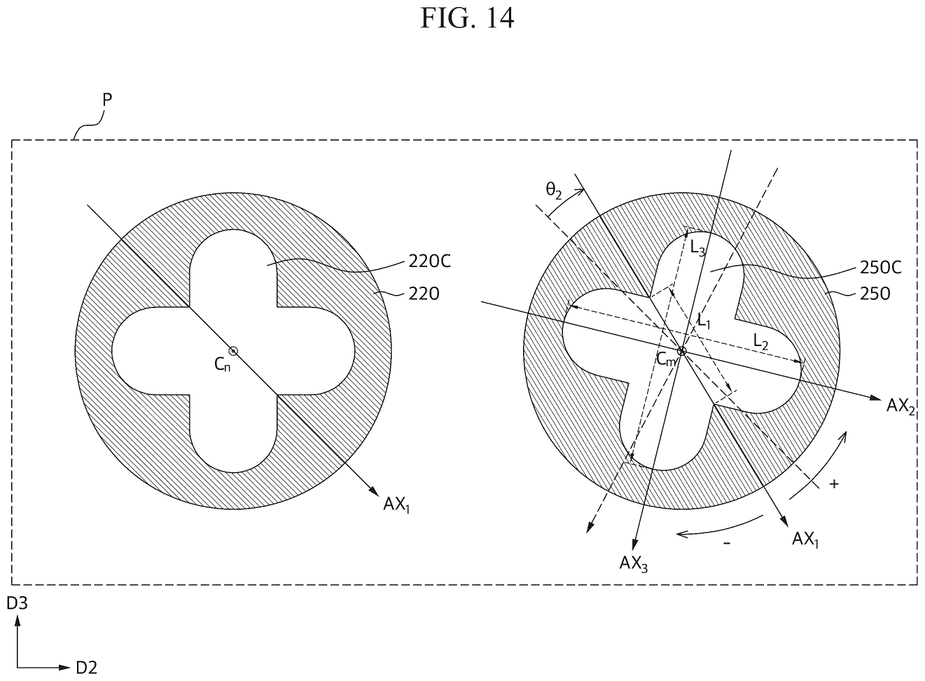

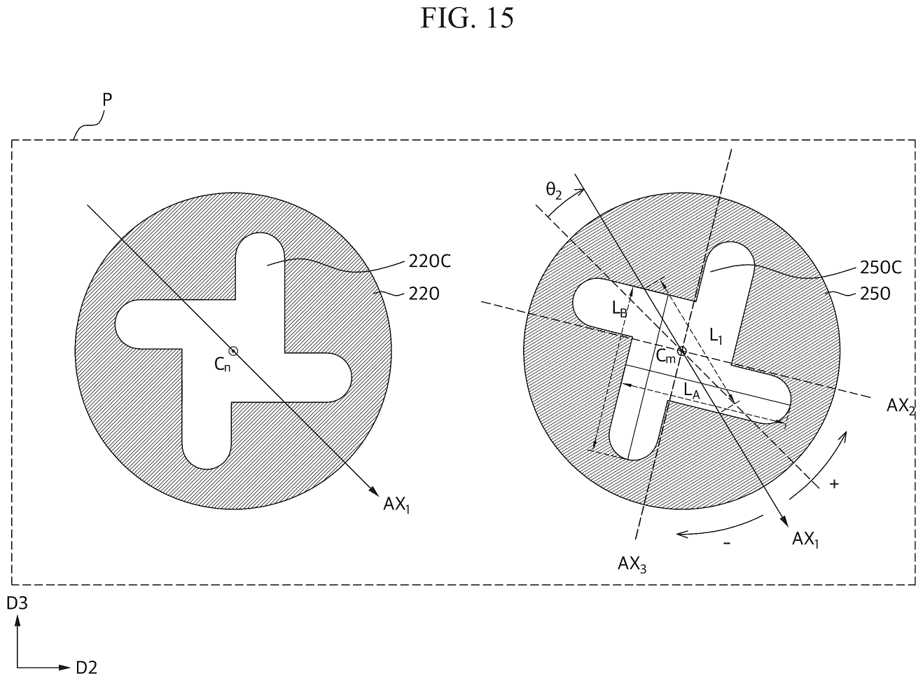

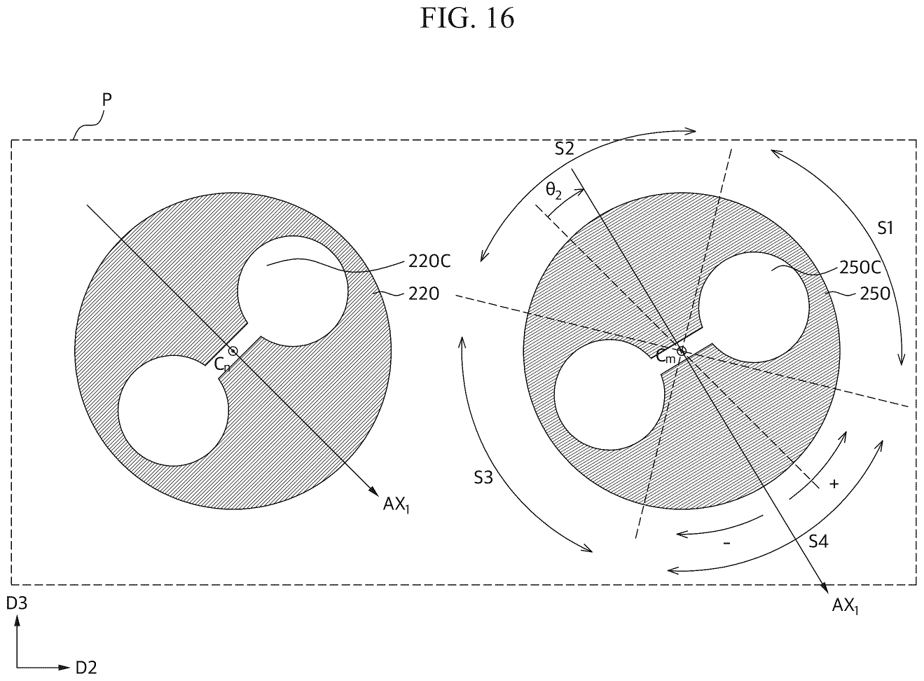

FIG. 14 is an enlarged view of the portion P of FIG. 8 illustrating bump pads (the first bump pad 220 and the second bump pad 250) and connectors (the first connector 220C and the second connector 250C) of the semiconductor device 10, according to some example embodiments, and illustrating the first connector 220C of the first shape and the second connector 250C of the first shape. FIG. 15 is an enlarged view of the portion P of FIG. 8 illustrating bump pads (the first bump pad 220 and the second bump pad 250) and connectors (the first connector 220C and the second connector 250C) of the semiconductor device 10, according to some example embodiments, and illustrating the first connector 220C of the second shape and the second connector 250C of the second shape. FIG. 16 is an enlarged view of the portion P of FIG. 8 illustrating bump pads (the first bump pad 220 and the second bump pad 250) and connectors (the first connector 220C and the second connector 250C) of the semiconductor device 10, according to some example embodiments, and illustrates the first connector 220C of the third shape and the second connector 250C of the third shape.

In some example embodiments, the semiconductor device 10 may include a plurality of first bump pads 220 and a plurality of second bump pads 250. In some example embodiments, the first connector 220C of at least one of the plurality of first bump pads 220 and the second connector 250C of at least one of the plurality of second bump pads 250 may have the same shape with a desired (or, alternatively, predetermined) rotation angle difference (Θ2) when viewed from the first direction D1 (e.g., in a plan view). In some example embodiments, the desired (or, alternatively, predetermined) rotation angle difference (Θ2) may be less than 90 degrees, and the direction of rotation may be clockwise or counterclockwise. In some example embodiments, when viewed from the first direction D1, the second connector 250C may have a shape selected from the first shape, the second shape and the third shape, as below. In some example embodiments, the second connectors 250C of at least one of the plurality of second bump pads 250 may have a shape selected from a first shape, a second shape and a third shape as viewed in the first direction D1. In some example embodiments, the second connector 250C of each of the plurality of second bump pads 250 may independently have a shape selected from a first shape, a second shape and a third shape when viewed from the first direction D1.

In some example embodiments, the second connector 250C of the second bump pad 250 may have the first shape, and in the first shape, the first length L₁, which is the length along the first axis direction AX₁ toward the center C_{S} of the substrate, passing through the center Cm of the second bump pad when viewed from the first direction D1, is shorter than the second length L₂, which is the length along the second axis direction AX₂ rotated 45 degrees counterclockwise from the first axis direction AX₁ while passing through the center Cm of the second bump pad, and the third length L₃, which is the length along the third axis direction AX₃ rotated 45 degrees clockwise from the first axis direction AX₁ while passing through the center Cm of the second bump pad. In some example embodiments, the stress generated due to the difference in the CTE, as described above, may act along the first axis direction AX₁. Referring to FIG. 14, there may be a desired (or, alternatively, predetermined) rotation angle difference (Θ2) compared to the first connector 220C of the first shape with respect to the second connector 250C of the first shape, and the desired (or, alternatively, predetermined) rotation angle difference (Θ2) may indicate the difference in rotation angle between the first axis direction AX₁ of the first connector 220C passing through the center Cn of the first bump pad and the first axis direction AX₁ of the second connector 250C passing through the center Cm of the second bump pad. In some example embodiments, in the second connector 250C of the first shape, the first length L₁ may be shorter than the second length L₂ and the third length L₃. In some example embodiments, the first shape may be a point-symmetrical shape based on the center Cm of the second bump pad. In some example embodiments, the first shape may be a line-symmetrical shape with respect to at least one of the first axis direction AX₁, the second axis direction AX₂ and the third axis direction AX₃. In some example embodiments, the first shape may be a point-symmetrical shape based on the center Cm of the second bump pad and a line-symmetrical shape based on at least one of the first axis direction AX₁, the second axis direction AX₂ and the third axis direction AX₃. In some example embodiments, the first shape may be a line-symmetrical shape with respect to all of the first axis direction AX₁, the second axis direction AX₂ and the third axis direction AX₃.

In some example embodiments, the second connector 250C of the second bump pad 250 may have a second shape different from the first shape. In the first length L₁ is shorter than the major axis length L_{A} of the second connector 250C parallel to the second axis direction AX₂ and the major axis length L_{B} of the second connector 250C parallel to the third axis direction AX₃. Referring to FIG. 15, there may be a desired (or, alternatively, predetermined) rotation angle difference (Θ2) compared to the first connector 220C of the second shape with respect to the second connector 250C in the second shape, and the desired (or, alternatively, predetermined) rotation angle difference (Θ2) may indicate the difference in rotation angle between the first axis direction AX₁ of the first connector 220C passing through the center Cn of the first bump pad and the first axis direction AX₁ of the second connector 250C passing through the center Cm of the second bump pad. In some example embodiments, the second connector 250C of the second shape may be different from the first shape, and the first length L₁ may be shorter than the major axis length L_{A} of the second connector 250C parallel to the second axis direction AX₂ and the major axis length L_{B} of the second connector 250C parallel to the third axis direction AX₃. In some example embodiments, the second shape may be a point-symmetrical shape with respect to the center Cm of the second bump pad. In some example embodiments, in the second shape, the major axis length L_{A} of the second connector 250C parallel to the second axis direction AX₂ and the major axis length L_{B} of the second connector 250C parallel to the third axis direction AX₃ may be longer than at least one of the length along the second axis direction AX₂ passing through the center Cm of the second bump pad and the length along the third axis direction AX₃ passing through the center Cm of the second bump pad.

In some example embodiments, the second connector 250C of the second bump pad 250 may have a third shape that is different from the first shape and the second shape. In the third shape, the sum of the surface area of the second connector 250C in the first area S1 rotated 45 degrees counterclockwise to 135 degrees counterclockwise in the first axis direction AX₁ and the surface area of the second connector 250C in the third area S3 rotated 45 degrees clockwise to 135 degrees clockwise from the first axis direction AX₁ is greater than the sum of the surface area of the second connector 250C in the second area S2 rotated 135 degrees counterclockwise to 225 degrees counterclockwise from the first axis direction AX₁ and the surface area of the second connector 250C in the fourth area S4 rotated 45 degrees clockwise or 45 degrees counterclockwise from the first axis direction AX₁. The semiconductor device 10 may reduce the stress caused by the difference in CTE, thereby reducing or lowering the defects occurring in the first solder bump 500, while reducing or preventing occurrence of EM. Referring to FIG. 16, there may be a desired (or, alternatively, predetermined) rotation angle difference (Θ2) compared to the first connector 220C of the third shape with respect to the second connector 250C of the third shape, and the desired (or, alternatively, predetermined) rotation angle difference (Θ2) may indicate the difference in rotation angle between the first axis direction AX₁ of the first connector 220C passing through the center Cn of the first bump pad and the first axis direction AX₁ of the second connector 250C passing through the center Cm of the second bump pad. In some example embodiments, in the third shape, the shape in the first area S1 and the shape in the third area S3 may be the same or similar to each other. Here, the third shape may be a point-symmetrical shape based on the center Cm of the second bump pad, and may be a line-symmetrical shape based on the first axis direction AX₁.

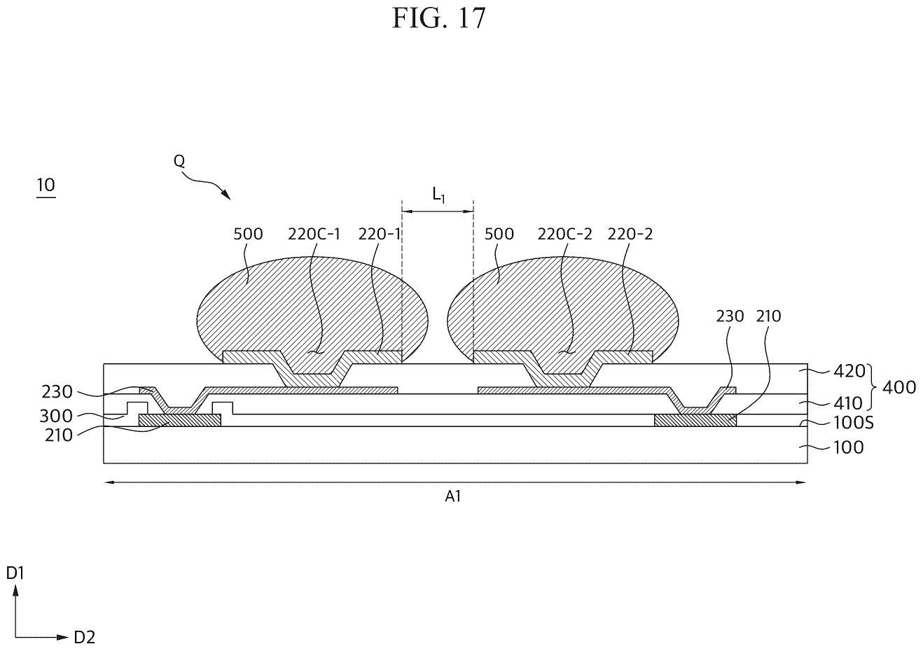

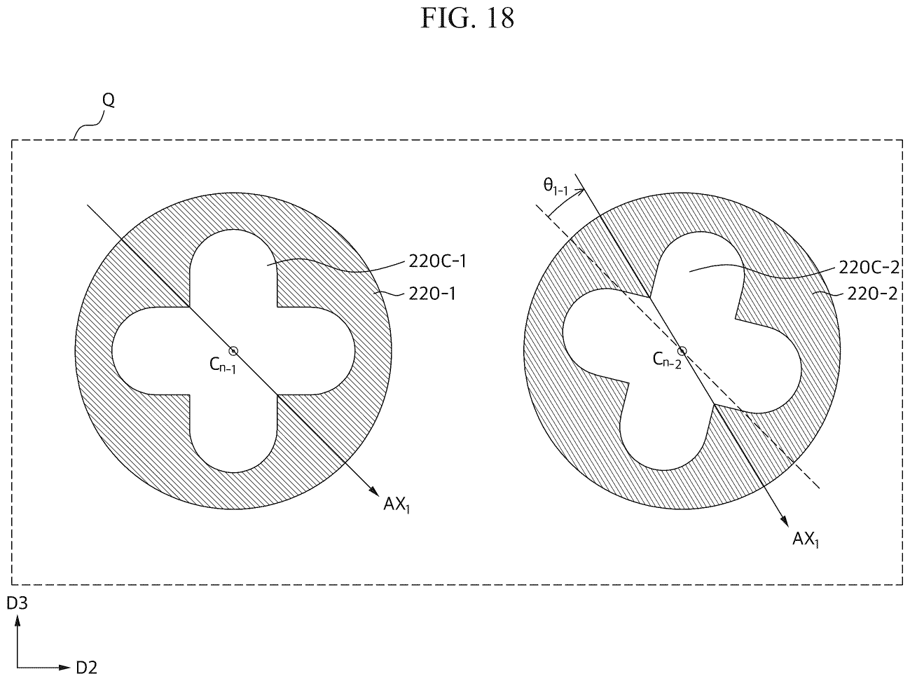

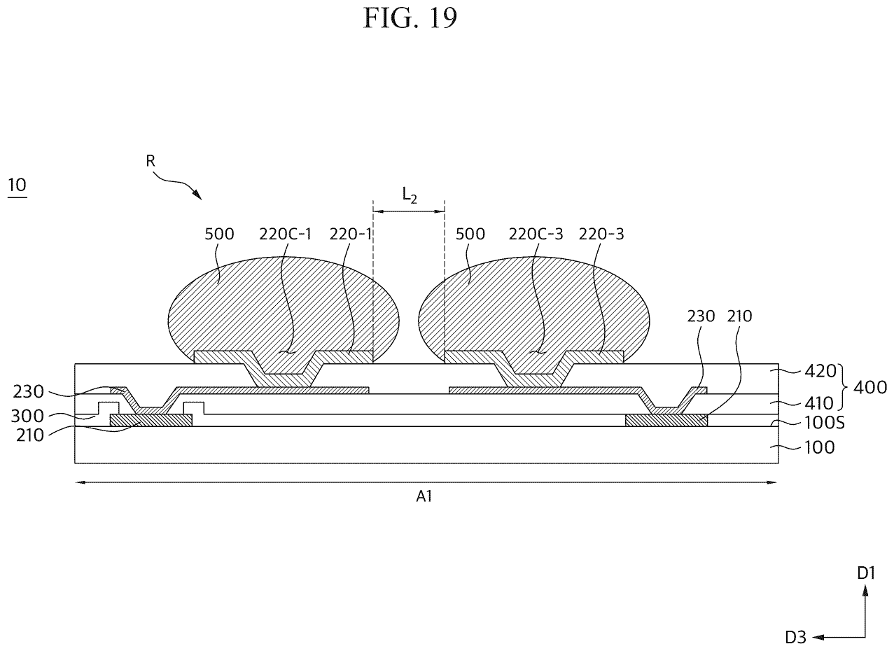

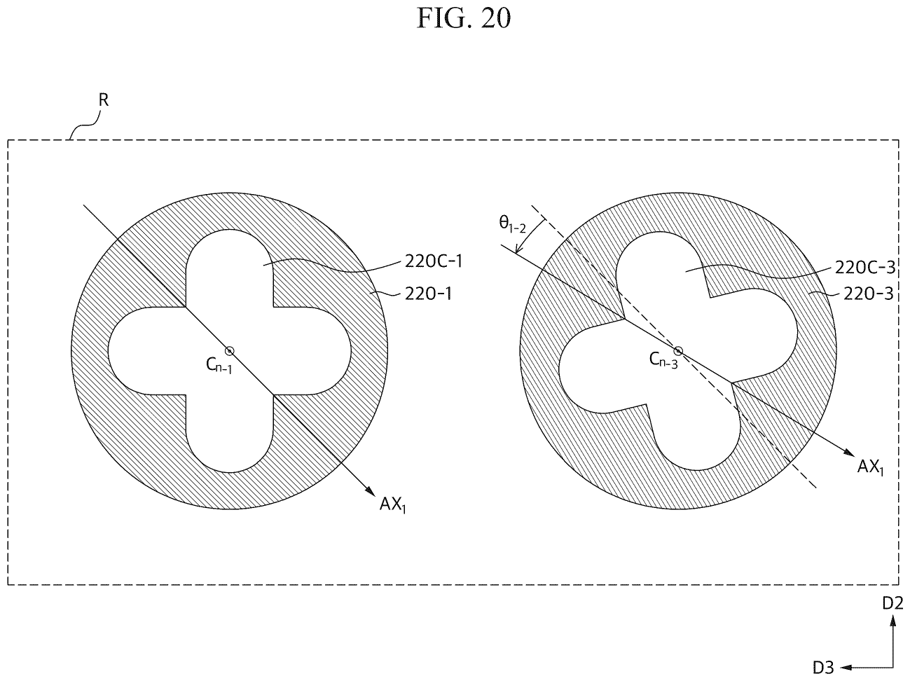

FIG. 17 is a cross-sectional diagram schematically illustrating the semiconductor device 10, according to some example embodiments, and illustrates a portion Q of FIG. 8. FIG. 18 illustrates bump pads (220-1, 220-2) and connectors (220C-1, 220C-2) of the semiconductor device 10 according to some example embodiments, and is an enlarged view of the portion Q of FIG. 8. FIG. 19 is a cross-sectional diagram schematically illustrating the semiconductor device 10 according to some example embodiments, and illustrates a portion R of FIG. 8. FIG. 20 illustrates bump pads (220-1, 220-3) and connectors (220C-1, 220C-3) of the semiconductor device 10 according to some example embodiments, and is an enlarged view of the portion R of FIG. 8. The semiconductor device 10 in FIGS. 17-20 may be same as or similar in some respects to the semiconductor device 10 of FIGS. 1-16, and therefore may be best understood with reference thereto where like numerals indicate like elements not described again in detail.

Referring to FIG. 18, in some example embodiments, some of the plurality of first bump pads 220 that are adjacent to each other may be arranged such that the first bump pads 220 are spaced apart from each other based on the second direction D2 and the third direction D3.

Referring to FIG. 17 and FIG. 19, among a plurality of first bump pads (220-1, 220-2 and 220-3), adjacent first bump pads may have the same distance L₁ from each other in the second direction D2 and the same distance L₂ from each other in the third direction D3.

In some example embodiments, among the plurality of first bump pads (220-1, 220-2 and 220-3), one first connector 220C-1 and one of another first connector 220C-2 spaced apart from each other based on the second direction D2 and another first connector 220C-3 spaced apart from each other based on the third direction D3 may have the same shape, having a desired (or, alternatively, predetermined) rotation angle difference (Θ_{1-1,} Θ₁₋₂) when viewed from the first direction D1 (e.g., in a plan view). In some example embodiments, the desired (or, alternatively, predetermined) rotation angle difference (Θ_{1-1,} Θ₁₋₂) may be less than 90 degrees, and the direction of the rotation may be clockwise or counterclockwise. Referring to FIG. 18, the one first connector 220C-1 of the first shape may have a desired (or, alternatively, predetermined) rotation angle difference (Θ_{1-1,}) compared to another first connector 220C-2 of the first shape spaced apart from each other based on the second direction D2. The desired (or, alternatively, predetermined) rotation angle difference may indicate the difference in rotation angle between the first axis direction AX₁ of one first connector 220C-1 passing through the center Cn₋₁ of the first bump pad of one first connector 220C-1 and the first axis direction AX₁ of another first connector 220C-2 passing through the center Cn₋₂ of the first bump pad of another first connector 220C-2 spaced apart from each other based on the second direction D2. Referring to FIG. 20, the one first connector 220C-1 of the first shape may have a desired (or, alternatively, predetermined) rotation angle difference (Θ₁₋₂) compared to the another first connector 220C-3 of the first shape spaced apart from each other based on the third direction D3. The desired (or, alternatively, predetermined) rotation angle difference (Θ₁₋₂) may indicate the difference in rotation angle between the first axis direction AX₁ of one first connector 220C-1 passing through the center Cn₋₁ of the first bump pad of one first connector 220C-1 and the first axis direction AX₁ of another first connector 220C-3 passing through the center Cn₋₃ of the first bump pad of another first connector 220C-3 spaced apart from each other based on the third direction D3.

While several example embodiments have been provided in the present disclosure, it should be understood that the disclosed example embodiments might be embodied in many other specific forms without departing from the spirit or scope of the present disclosure. The examples embodiments are to be considered as illustrative and not restrictive, and the intention is not to be limited to the details given herein. For example, the various elements or components may be combined or integrated in another system or certain features may be omitted, or not implemented.

What is claimed is:

1. A semiconductor device comprising:
a substrate;
a substrate pad on the substrate;
a substrate insulation layer configured to surround at least a portion of the substrate pad;
a passivation layer on the substrate insulation layer; and
a bump pad on the passivation layer, electrically connected to the substrate pad, and including solder bumps,
wherein the bump pad comprises a connector recessed toward the substrate, and
wherein the connector, when viewed in a first direction perpendicular to a surface of the substrate, comprises a shape including at least one of,
a first shape having a first length L₁ shorter than a second length L₂ and a third length L₃,
the first length L₁ being along a first axis direction passing through a center of the bump pad and toward the center of the substrate,
the second length L₂ being along a second axis direction, the second axis direction being rotated 45 degrees counterclockwise from the first axis direction while passing through the center of the bump pad, and
the third length L₃ being along a third axis direction, the third axis direction being rotated 45 degrees clockwise from the first axis direction while passing through the center of the bump pad;
a second shape having the first length L₁ shorter than a major axis length L_{A} of the connector parallel to the second axis direction and a major axis length L_{B} of the connector parallel to the third axis direction, the second shape being different from the first shape; and
a third shape, in which a sum of a surface area of the connector in a first area rotated 45 degrees counterclockwise to 135 degrees counterclockwise from the first axis direction and a surface area of the connector in a third area rotated 45 degrees clockwise to 135 degrees clockwise from the first axis direction is greater than a sum of a surface area of the connector in a second area rotated 135 degrees counterclockwise to 225 degrees counterclockwise from the first axis direction and a surface area of the connector in a fourth area rotated 45 degrees clockwise or 45 degrees counterclockwise from the first axis direction, the third shape being different from the first shape and the second shape.

2. The semiconductor device of claim 1, wherein the first shape is a point-symmetrical shape based on the center of the bump pad.

3. The semiconductor device of claim 1, wherein the first shape is a line-symmetrical shape based on at least one of the first axis direction, the second axis direction, and the third axis direction.

4. The semiconductor device of claim 1, wherein the first shape is a line-symmetrical shape based on each of the first axis direction, the second axis direction, and the third axis direction.

5. The semiconductor device of claim 1, wherein the second shape is a point-symmetrical shape based on the center of the bump pad.

6. The semiconductor device of claim 5, wherein, in the second shape,
the major axis length L_{A} of the connector parallel to the second axis direction and the major axis length L_{B} of the connector parallel to the third axis direction are longer than at least one of a length along the second axis direction passing through the center of the bump pad and a length along the third axis direction passing through the center of the bump pad.

7. The semiconductor device of claim 1, wherein the substrate pad and the bump pad do not contact each other.

8. The semiconductor device of claim 7, further comprising:
a redistribution line (RDL) electrically connected to the substrate pad and the bump pad.

9. The semiconductor device of claim 8, wherein the RDL is within the passivation layer.

10. The semiconductor device of claim 1, wherein the substrate pad and the bump pad overlap each other at least in an area when viewed from the first direction.

11. The semiconductor device of claim 10, wherein the passivation layer contacts at least a portion of the substrate pad and at least a portion of the bump pad.

12. A semiconductor device comprising:
a substrate comprising a first area extending from an edge toward a center of the substrate and a second area that is an area of the substrate excluding the first area;
a first substrate pad on the first area and a second substrate pad on the second area;
a substrate insulation layer surrounding at least a portion of each of the first substrate pad and the second substrate pad;
a passivation layer on the substrate insulation layer;
a first bump pad on the passivation layer, electrically connected to the first substrate pad, and including a first solder bump; and
a second bump pad on the passivation layer, electrically connected to the second substrate pad, and including a second solder bump,
wherein the first bump pad comprises a first connector that is recessed toward the first area, and the second bump pad comprises a second connector that is recessed toward the second area, and
wherein the first connector, when viewed in a first direction perpendicular to a surface of the substrate, comprises a shape including at least one of,
a first shape having a first length L₁ shorter than a second length L₂ and a third length L₃,
the first length L₁ being along a first axis direction passing through a center of the first bump pad toward a center of the substrate,
the second length L₂ being along a second axis direction, the second axis direction being rotated 45 degrees counterclockwise from the first axis direction while passing through the center of the first bump pad, and
the third length L₃ being along a third axis direction, the third axis direction being rotated 45 degrees clockwise from the first axis direction while passing through the center of the first bump pad;
a second shape having the first length L₁ shorter than a major axis length L_{A} of the first connector parallel to the second axis direction and a major axis length L_{B} of the first connector parallel to the third axis direction, the second shape being different from the first shape; and
a third shape, in which a sum of a surface area of the first connector in the first area rotated 45 degrees counterclockwise to 135 degrees counterclockwise from the first axis direction and a surface area of the first connector in a third area rotated 45 degrees clockwise to 135 degrees clockwise from the first axis direction is greater than a sum of a surface area of the first connector in the second area rotated 135 degrees counterclockwise to 225 degrees counterclockwise from the first axis direction and a surface area of the first connector in a fourth area rotated 45 degrees clockwise or 45 degrees counterclockwise from the first axis direction, the third shape being different from the first shape and the second shape.

13. The semiconductor device of claim 12, wherein the semiconductor device includes a plurality of first bump pads, the plurality of first bump pads including the first bump pad.

14. The semiconductor device of claim 13, comprising an arrangement in which at least two first bump pads adjacent to each other among the plurality of first bump pads are parallel to the surface of the substrate, are spaced apart from each other in a second direction that intersects the first direction, and are spaced apart from each other in a third direction that is parallel to the surface of the substrate and intersects with the second direction.

15. The semiconductor device of claim 14, wherein,
with respect to at least two first bump pads adjacent to each other among the plurality of first bump pads, a distance between the at least two first bump pads in the second direction and a distance between the at least two first bump pads in the third direction are same.

16. The semiconductor device of claim 14, wherein,
with respect to at least two first bump pads adjacent to each other among the plurality of first bump pads, the semiconductor device includes the first connector, the second connector, and a third connector,
wherein, when viewed from the first direction, the first connector and the second connector are spaced apart from each other in the second direction and the first connector and the third connector are spaced apart from each other in the third direction, and a shape of the third connector is same as the shape of the first connector and is rotated with respect to the first connector by a rotation angle, and
wherein the rotation angle is less than 90 degrees.

17. The semiconductor device of claim 12, wherein,
when viewed from the first direction, a surface area of the shape of the first connector is a same as a surface area of a shape of the second connector or is larger than a surface area of the shape of the second connector.

18. The semiconductor device of claim 13, wherein,
the semiconductor device includes a plurality of second bump pads, and the second connector of at least one of the plurality of second bump pads is circular in shape when viewed from the first direction.

19. The semiconductor device of claim 13, wherein,
the semiconductor device includes a plurality of second bump pads,
the first connector of at least one of the plurality of first bump pads and the second connector of at least one of the plurality of second bump pads have a same shape and are rotated by a rotation angle with respect to each other when viewed from the first direction, and
wherein the rotation angle difference is less than 90 degrees.

20. A semiconductor device comprising:
a substrate comprising a first area extending from an edge toward a center of the substrate and a second area that is an area of the substrate excluding the first area;
a first substrate pad on the first area and a second substrate pad on the second area;
a substrate insulation layer surrounding at least a portion of each of the first substrate pad and the second substrate pad;
a passivation layer on the substrate insulation layer;
a first bump pad on the passivation layer, electrically connected to the first substrate pad, and including a first solder bump; and
a second bump pad on the passivation layer, electrically connected to the second substrate pad, and including a second solder bump,
wherein the first bump pad comprises a first connector that is recessed toward the first area, and the second bump pad comprises a second connector that is recessed toward the second area,
wherein the first connector, when viewed in a first direction perpendicular to a surface of the substrate, comprises a shape including at least one of,
a first shape having a first length L₁ shorter than a second length L₂ and a third length L₃,
the first length L₁ being along a first axis direction passing through a center of the first bump pad toward a center of the substrate,
the second length L₂ being along a second axis direction, the second axis direction being rotated 45 degrees counterclockwise from the first axis direction while passing through the center of the first bump pad, and
the third length L₃ being along a third axis direction, the third axis direction being rotated 45 degrees clockwise from the first axis direction while passing through the center of the first bump pad;
a second shape having the first length L₁ shorter than a major axis length L_{A} of the first connector parallel to the second axis direction and a major axis length L_{B} of the first connector parallel to the third axis direction, the second shape being different from the first shape; and
a third shape, in which a sum of a surface area of the first connector in the first area rotated 45 degrees counterclockwise to 135 degrees counterclockwise from the first axis direction and a surface area of the first connector in a third area rotated 45 degrees clockwise to 135 degrees clockwise from the first axis direction is greater than a sum of a surface area of the first connector in the second area rotated 135 degrees counterclockwise to 225 degrees counterclockwise from the first axis direction and a surface area of the first connector in a fourth area rotated 45 degrees clockwise or 45 degrees counterclockwise from the first axis direction, the third shape being different from the first shape and the second shape,
wherein the semiconductor device comprises an arrangement in which at least two first bump pads adjacent to each other among a plurality of first bump pads are parallel to the surface of the substrate, are spaced apart from each other in a second direction which intersects the first direction, and are spaced apart from each other in a third direction that is parallel to the surface of the substrate and intersects with the second direction,
wherein, with respect to at least two first bump pads adjacent to each other among the plurality of first bump pads, the semiconductor device includes the first connector, the second connector, and a third connector,
wherein, when viewed from the first direction, the first connector and the second connector are spaced apart from each other in the second direction and the first connector and the third connector are spaced apart from each other in the third direction, and the third connector has a shape that is same as a shape of the first connector and is rotated with respect to the first connector by a rotation angle,
wherein the rotation angle is less than 90 degrees, and
wherein, when viewed from the first direction, a surface area of the shape of the first connector is a same as a surface area of a shape of the second connector, or the surface area of the shape of the first connector is larger than the surface area of the shape of the second connector.
